(19) United States
(12) Patent Application Publication
(10) Pub. No.: US 2003/0113991 A1
(43) Pub. Date: Jun. 19, 2003

(54) Semiconductor device manufacturing method

(75) Inventor: Tooru Maeda, Tachikawa-shi (JP)

Correspondence Address: Koda & Androlia, 2029 Century Park East, Suite 3850, Los Angeles, CA, 90067, US

(73) Assignee: Kabushiki Kaisha Shinkawa

(21) Appl. No.: 10/307,081

(22) Filed: Nov. 27, 2002

(30) Foreign Application Priority Data
Nov. 28, 2001 (JP) 2001-362132

(51) Int. Cl. H01L 21/301; H01L 21/46; H01L 21/78; H01L 21/44

(52) U.S. Cl. 438/612; 438/460

(57) ABSTRACT

A wire bonding method in which conductive patterns that are electrically connected at one end to pads are formed on the surface of a wafer on which a plurality of pads have been formed, and bumps used as connecting points located on the other ends of the conductive patterns are connected to the connecting terminals of a substrate. A disposition of bumps that differs from the disposition of the pads is obtained by the conductive patterns, thus eliminating and adjusting mismatching between the disposition of the pads and the disposition of the connecting terminals.

### BACKGROUND OF THE INVENTION

1. Field of the Invention

The present invention relates to a semiconductor device manufacturing method and more particularly to a semiconductor device manufacturing method that increases the efficiency of the semiconductor device manufacturing process.

2. Prior Art

In manufacturing processes for semiconductor devices, numerous desired integrated circuits are formed on a wafer (semiconductor substrate), and the wafer is diced (split) along each of these integrated circuits so that numerous dies (semiconductor elements) are formed, after which pads formed as electrodes on these dies and connecting terminals of substrate lead frames, etc. are connected.

In wire bonding that is performed in order to connect such pads and connecting terminals, the tip end of a gold wire that is caused to protrude from the tip end of a capillary is melted so that a gold ball is formed. This gold ball is first joined to the pad by applying an ultrasonic vibration while the gold ball is pressed against the pad on the die (after splitting) by a specified load; next, the capillary is moved to the side of the substrate lead frame while the gold wire is paid out from the capillary, and the other end of the gold wire is connected to the lead of the lead frame, after which the gold wire is cut.

Furthermore, in the case of flip-chip bonding that uses bumps formed on the pads, protruding bumps are formed by joining gold balls to the pads on the dies after splitting and then by cutting the gold wire. The dies are then inverted and caused to cover the connecting terminals of a mounting substrate, etc., and the pads and connecting terminals are connected.

However, in the respective methods described above, it is difficult to join dies that have a common pad disposition to substrates that have different dispositions of connecting terminals due to type differences. It is also difficult to join a plurality of different types of dies with different pad dispositions caused by type differences to a substrate that has a common connecting terminal disposition.

### SUMMARY OF THE INVENTION

Accordingly, the object of the present invention is to provide a semiconductor device manufacturing method that absorbs or adjusts mismatches in the disposition of connecting terminals and the disposition of pads.

The above object is accomplished by unique steps of the present invention for a semiconductor device manufacturing method that includes:

a conductive pattern formation step in which a plurality of conductive patterns that are electrically connected at one ends thereof to a plurality of pads are formed on an integrated circuit on which the plurality of pads are formed, and

a connecting step in which connecting points located at other ends of the conductive patterns are connected to a substrate; and

a disposition of the connecting points that differs from a disposition of the pads is obtained by means of the conductive patterns.

In other words, according to the present invention, in the conductive pattern formation step, the connecting points are formed at different locations from the pads on an integrated circuit.

As seen from the above, in the method of the present application, a plurality of conductive patterns that are electrically connected at one end to a plurality of pads are formed on the integrated circuit on which a plurality of pads are formed in the conductive pattern formation step, and the disposition of connecting points that differs from the disposition of the pads is obtained by means of these conductive patterns. Then, in the connecting step, these connecting points are connected to the substrate. Thus, since the connecting points that have a disposition which is different from the disposition of the pads are formed, mismatching between the disposition of the pads and the disposition of the connecting terminals can be avoided.

In the above method of the present invention, the conductive pattern formation step includes a protective layer formation step in which a resin layer is formed as an outer layer on the conductive patterns. Since the resin layer is formed on the conductive patterns, the conductive patterns can be protected from damage or contamination by the resin layer. Furthermore, this technique differs from the case of molding by resin packaging in conventional wire bonding in that the danger of short-circuiting caused by movement of the gold wire following joining due to flow of the molten resin can be eliminated.

Furthermore, in the method of the present invention, the conductive pattern formation step forms intersection portions in which the plurality of conductive patterns intersect. Since the intersection portions in which the plurality of conductive patterns intersect are formed, the degree of freedom in the disposition of the connecting points increases greatly.

Furthermore, in the method of the present application, the conductive pattern formation step includes a bump formation step in which bumps used for flip-chip bonding are formed on the connecting points. Since bumps used for flip-chip bonding are formed on the connecting points, the respective effects described above can be realized in a flip-chip bonding system.

In addition, in the present invention, the bump formation step includes a trapezoidal portion formation step that forms a resin layer on the surface of the integrated circuit and a conductive layer formation step that forms a conductive layer as an outer layer on the resin layer. Since bumps are formed by forming a conductive layer as an outer layer on the resin layer, savings can be made in the amount of material of the conductive layer used for the bumps.

The above-described resin layer possesses elasticity when cured. As a result of the elasticity of the resin layer, mechanical shock during assembly can be alleviated, and dimensional error of the individual bumps is absorbed. Thus, the reliability of the product can be improved.

In the present invention, the conductive patterns can be suitably formed by sintering a conductive powder, or such patters can be comprised of a photo-setting resin that contains a conductive powder. Furthermore, the resin layer can be comprised of an insulating photo-setting resin. With these conductive patterns and the resin layer, a process that involves collisions is not taken; and since the application of heat is local, the reliability of the product improves.

Furthermore, in the present invention, the conductive pattern formation step is performed simultaneously for a plurality of integrated circuits that are formed on a wafer prior to dicing. Since the conductive pattern formation step is performed simultaneously for a plurality of integrated circuits formed on the wafer prior to dicing, the manufacturing efficiency can be greatly improved compared to a case in which such a step is performed separately for individual die.

Furthermore, in the present invention, the protective layer formation step is performed simultaneously for a plurality of integrated circuits formed on a wafer prior to dicing. Since the protective layer formation step is performed simultaneously for a plurality of integrated circuits formed on the wafer prior to dicing, the manufacturing efficiency can be greatly improved compared to a case in which such a step is performed separately for individual die.

### BRIEF DESCRIPTION OF THE DRAWINGS

FIG. 1 is a perspective view of a wafer processing apparatus used in carrying out the method of the present invention;

FIGS. 2A through 2E show, in cross section, the steps of the semiconductor device manufacturing method according to one embodiment of the present invention;

FIG. 3 is a sectional view showing the step in which a bump is joined to a connecting terminal;

FIG. 4 is a perspective view of one example of a die during manufacture by the method of the embodiment;

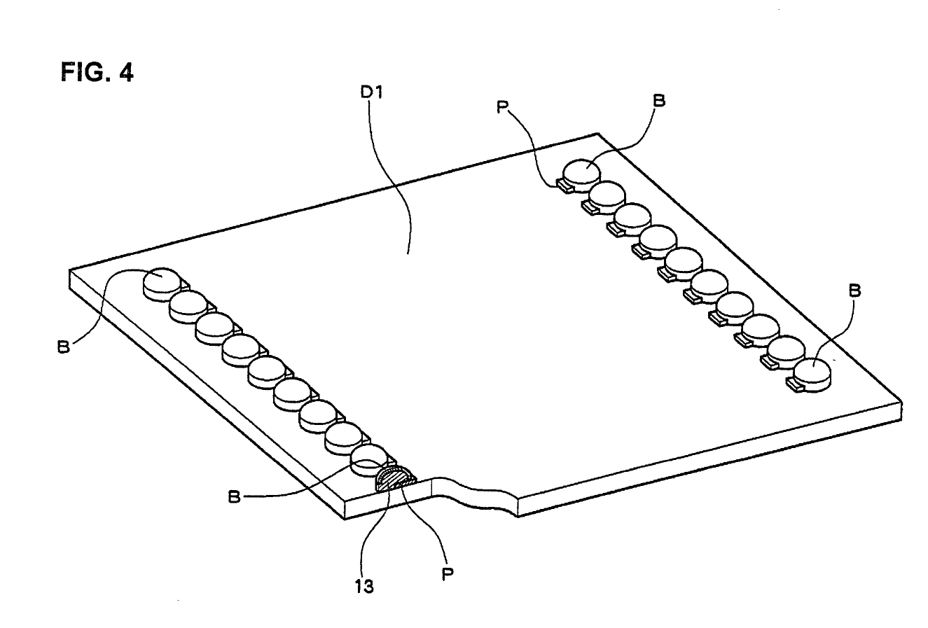

FIG. 5 is a perspective view of another example of a die during manufacture by the method of the embodiment;

FIG. 6 is a perspective of one example of a die during manufacture by the method of the present invention in which intersection portions of the conductive patterns are formed;

FIG. 7 is a perspective view of the essential portion of the die in which intersection portions of the conductive patterns are formed, FIG. 7 representing the area encircled in FIG. 6; and

FIGS. 8A through 8D show, in cross section, the steps of the modified semiconductor device manufacturing method of the present invention in which an electrostatic duplicating process is employed when forming the conductive pattern.

### DETAILED DESCRIPTION OF THE INVENTION

Embodiments of the present invention will be described below with reference to the accompanying drawings.

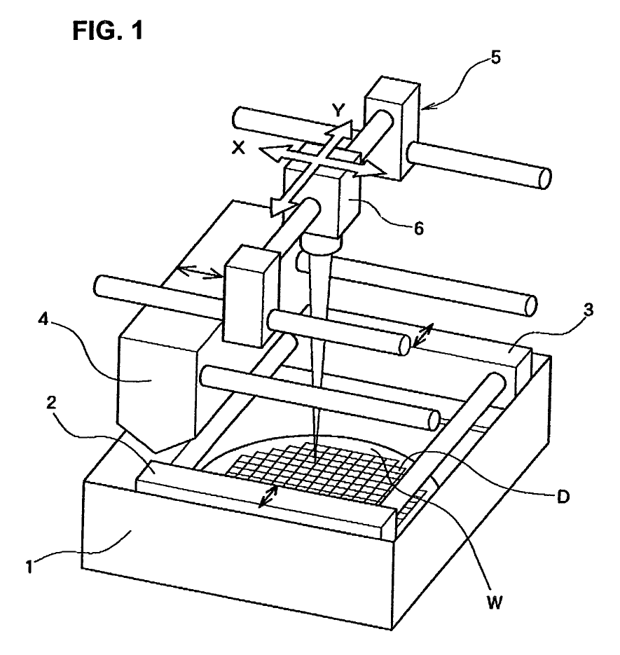

In FIG. 1, the wafer processing apparatus that carries out the present invention includes a case 1, an insulator supply device 2, a conductor supply device 3, an uncured material removing device 4, an XY stage 5, and a light source 6.

The case 1 is a box-form body which is formed with substantially the shape of a rectangular solid, and it is open at the top. A wafer W which has not yet been diced is disposed inside this case 1. The insulator supply device 2 supplies an insulating resin in a semi-fluid state to the upper surface of the wafer W. The conductor supply device 3 supplies a powdered conductive substance to the upper surface of the undiced wafer W.

The uncured material removing device 4 removes the unnecessary portions of the materials supplied by the insulator supply device 2 and conductor supply device 3. The uncured material removing device 4 has a cleaning liquid jetting function and drying air discharging function.

The XY stage 5 moves the light source 6 into any desired position in two dimensions (i.e., in the directions of the X axis and Y axis, which are perpendicular to each other in the horizontal direction) by means of an internal motor (not shown). The light source 6 cures the insulating resin or sinters the conductive substance by emitting laser light, and it has a focal length altering function in order to allow effective irradiation of materials of different heights.

The insulating resin used in the shown embodiment is a photo-setting fluid resin which is cured by the laser light from the light source 6 and possesses toughness and elastic resilience following curing. For example, the resin consists of three elements: an oligomer (epoxy acrylate or urethane acrylate, etc.), a reactive diluent (monomer) and a photopolymerization initiator (benzoin type, acetophenone type, etc.).

The conductive substance used in this embodiment is a powdered conductive substance which can be sintered by laser light from the light source 6, e.g., a copper or aluminum powder.

Processes that form a conductive layer and an insulating layer on the surface of the undiced wafer W will be described.

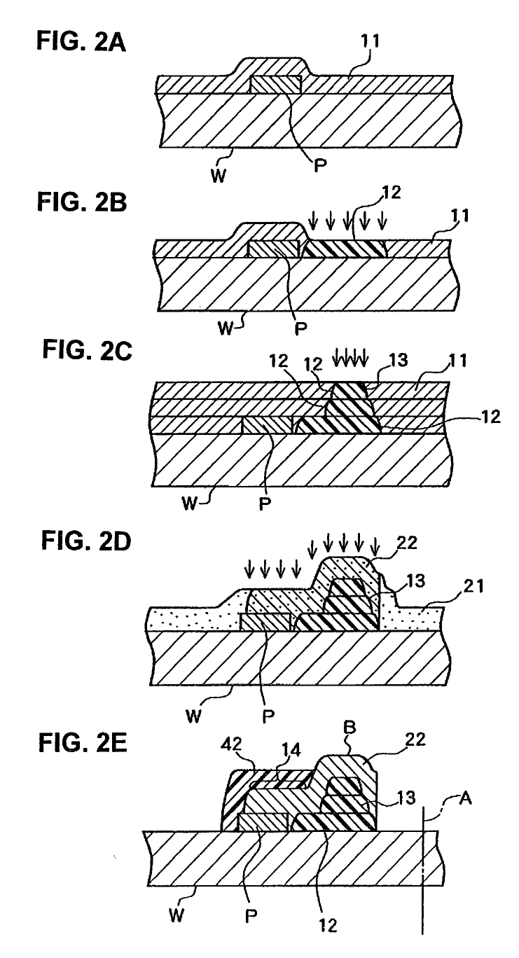

In FIG. 2A, a liquid-form insulator 11 which possesses fluidity is first supplied by the insulator supply device 2 to the upper surface of the wafer W on which pads P have been formed.

Next, as shown in FIG. 2B, a portion of the insulator 11 is cured by irradiation with light from the light source 6, so that a cured insulating layer 12 is formed.

These steps are repeatedly performed in accordance with the desired shape; and a portion of the cured insulating layer 12 is laminated to a considerable height so that a trapezoidal portion 13 is formed as shown in FIG. 2C. Then, the supply of a cleaning liquid and the supply of drying air are performed by the uncured material removing device 4; as a result, the uncured insulator 11 is removed, thus bringing a state in which the pad P and trapezoidal portion 13 remain on the surface of the wafer W.

Next, as shown in FIG. 2D, a powdered conductive substance 21 is supplied by the conductor supply device 3, and a portion of this conductive substance 21 is sintered or cured by irradiation with light from the light source 6, so that a conductive layer 22 is formed.

Then, the supply of a cleaning liquid and the supply of drying air are performed by the uncured material removing device 4. As a result, the uncured conductive substance 21 is removed. Finally, the supply of the conductor 11, curing by irradiation with laser light and removal of the uncured material are performed again, thus forming an insulating protective layer 42 as shown in FIG. 2E. As a result of the above, a conductive pattern 14 which is electrically connected at one end to the pad P, and a bump B which is electrically connected to the conductive pattern 14, are formed.

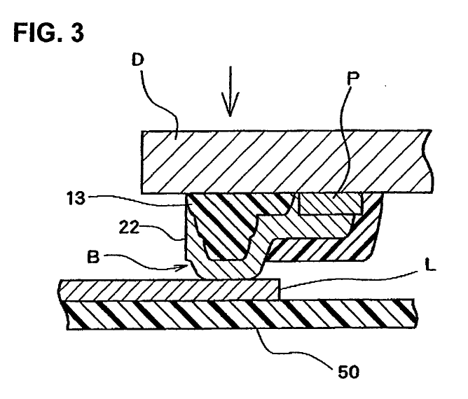

Afterward, the wafer W is diced along, for instance, line A in FIG. 2E, thus producing the die D shown in FIG. 3. Using a flip-chip bonding system, the die D is turned over so that the bump B faces the connecting terminal L of a lead frame used as a connecting terminal that is held on a mounting substrate 50 and is joined to this connecting terminal L by the application of pressure and an ultrasonic vibration. This joining can be accomplished with a light load using a paste solder.

In the above embodiment, as described above, conductive patterns 14 which are electrically connected at one end to pads P are formed on an integrated circuit on which a plurality of pads P are formed, and bumps B used as connecting points located at the other ends of the conductive patterns 14 are connected to the connecting terminals L of a substrate. Accordingly, the conductive pattern 14 has a disposition of bumps B that differs from the disposition of the pads P. As a result, mismatching between the disposition of the pads P and the disposition of the connecting terminals L can be absorbed or adjusted and thus eliminated.

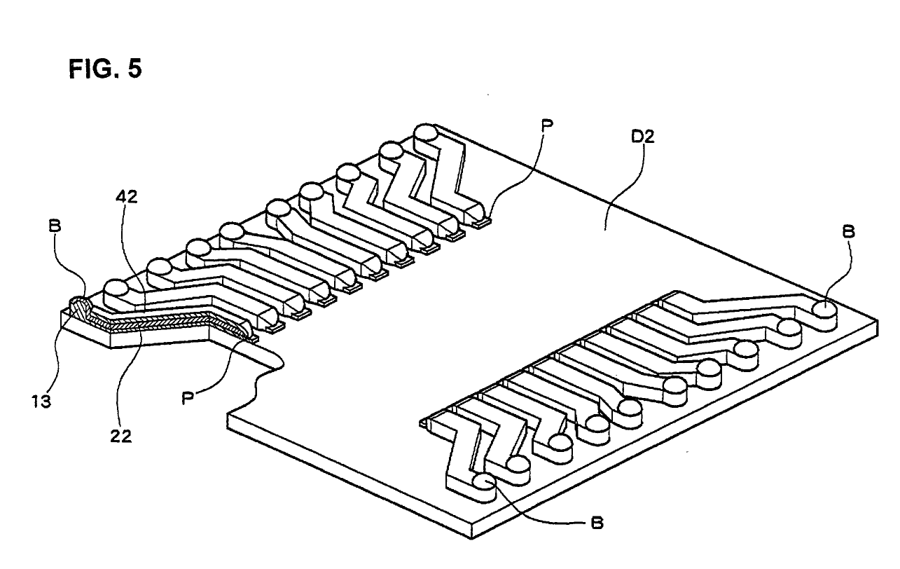

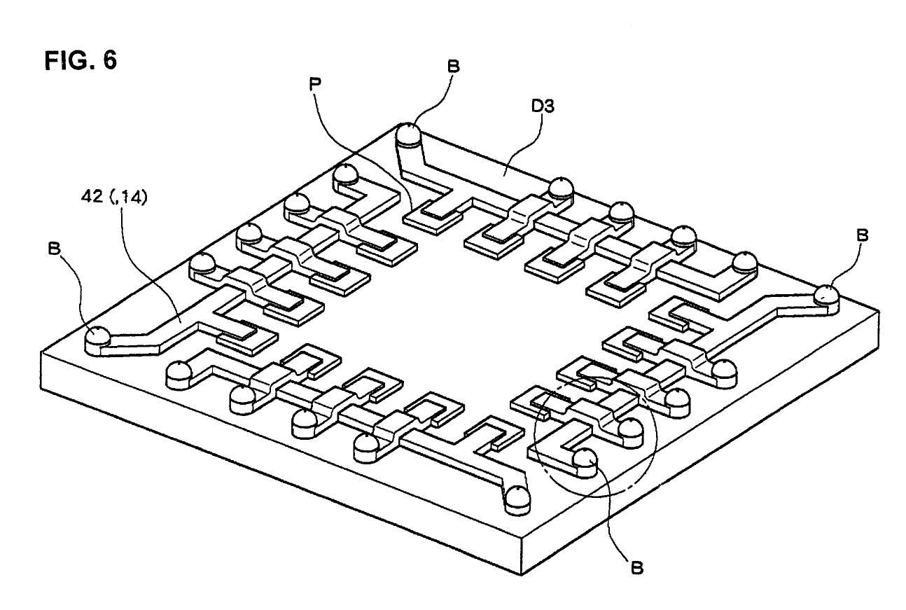

In other words, in the shown embodiment, by way of altering the dimensions of the conductive patterns 14, a common disposition of bumps B can be obtained for a plurality of different types of dies D1 and D2 (see FIGS. 5 and 6) with different dispositions of pads P. As a result, the dies D1 and D2 can be connected to connecting terminals of common dimensions.

Furthermore, in the above embodiment, the protective layer 42 is formed as a resin layer on the outer surface of the conductive patterns 14. Accordingly, the conductive patterns 14 are protected from damage and contamination by the protective layer 42. Furthermore, with the structure that has the protective layer 42, unlike the case of molding by resin packaging in conventional wire bonding, the danger of short-circuiting caused by movement of the gold wire following joining due to flow of the molten resin can be eliminated. Moreover, by way of providing such a protective layer 42 that covers not only the upper surfaces of the pads P but also the side surfaces of the pads P, a greatly increased protective effect with respect to the pads P is assured. Furthermore, the protective layer 42 can be formed so as to cover the entire upper surface of each die D except for the conductive layer 22 that is on the surface of the bump B.

In the formation step for the bumps B of the above embodiment, the trapezoidal portion 13 consisting of a resin is first formed on the wafer W, and a conductive pattern 14 is then formed on the outer surface (upper surface in FIG. 2) of this trapezoidal portion 13. Accordingly, a saving can be made in the amount of conductive material used for the bumps B.

Furthermore, a material that possesses elasticity following curing is used as the resin material that forms the trapezoidal portions 13. Accordingly, the mechanical shock that occurs during assembling process (joining with the connecting terminals L) can be alleviated by the elasticity of the trapezoidal portions 13, and dimensional error of the individual bumps B (especially the variation in the height) can be absorbed by means of a light load corresponding to the elasticity of the trapezoidal portions 13. As a result, the reliability of the product can be improved.

Furthermore, the conductive patterns 14 are formed by sintering a conductive powder, and the cured insulating layer 12 and protective layer 42 are formed by means of an insulating photo-setting resin. Accordingly, there is no process that involves collisions, and the application of heat is local. Thus, the reliability of the product can be improved.

Furthermore, in the above embodiment, the cured insulating layer 12 and protective layer 42 are formed by the so-called free liquid level method. However, it is also possible to form these layers by a photo-setting resin molding process using some other method such as a restricted liquid level method, etc. Moreover, the cured insulating layer 12 and protective layer 42 can be formed by other forming method such as application of the resin by a silk screen process, etc., and other materials may also be used.

Furthermore, in the above embodiment, the light source that emits laser light is used as the light source 6. However, it is also possible to use a light source with different properties as the light source 6 in accordance with the material of the conductive patterns 14. For example, a light source emitting X-rays, ultraviolet light or visible light can be used.

In the above embodiment, the light source 6 has a focal length altering function. Accordingly, an XY stage 5 that can move the light source 6 in two dimensions (i.e., in the directions of the X axis and Y axis, which are two axes perpendicular to each other in the horizontal direction) is sufficient; and there is no need for any structure or control that moves the light source 6 in the direction of Z axis (i.e., in the vertical direction). However, the XY stage 5 can be a stage that is capable of moving in the vertical direction.

Furthermore, in the shown embodiment, the step in which the conductive patterns 14 are formed is performed at once or simultaneously for all of the plurality of integrated circuits (die D) formed on the undiced wafer W. Accordingly, the manufacturing efficiency is greatly improved compared to a case in which the same step is performed separately for individual die D after dicing, thus contributing to a reduction in cost.

In the above embodiment, the step that forms the protective layer 42 is performed at once or simultaneously for all of the plurality of integrated circuits (die D) formed on the undiced wafer W. Accordingly, the manufacturing efficiency is greatly improved compared to a case in which the same step is performed separately for individual die D after dicing, thus contributing to a reduction in cost.

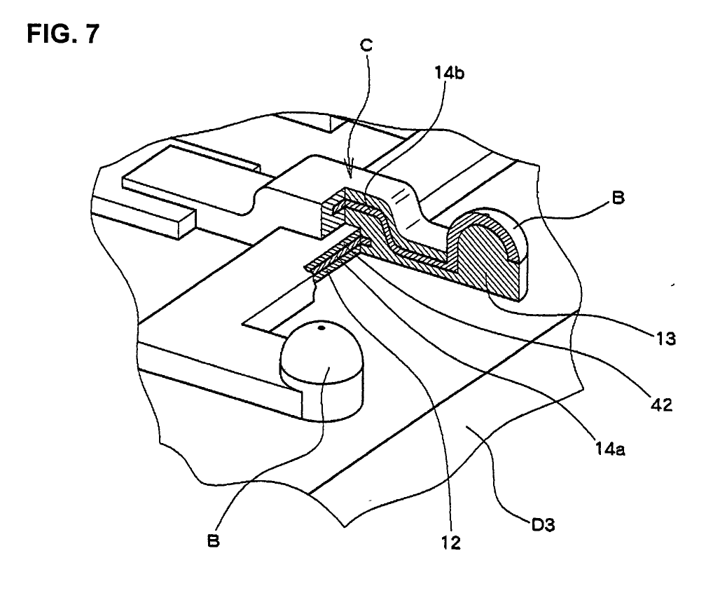

In the above embodiment, the conductive patterns 14 are formed as single layers. However, the conductive patterns used in the present invention can be formed in a plurality of layers. For example, it is possible to form intersection portions C in which a plurality of conductive patterns 14a and 14b formed on the surface of the die D3 intersect with each other as shown in FIGS. 6 and 7. With this structure involving the intersected conductive patterns, the degree of freedom in the disposition of the bumps B that form the connecting points, and the degree of freedom in the disposition of the pads P, are greatly improved.

Furthermore, in the shown embodiment, bumps B are formed on the conductive patterns 14 so as to be at the connecting points with a substrate (connecting terminals L). Accordingly, the respective effects described above can be realized in a flip-chip bonding system. However, instead of forming the bumps B on the connecting points of the conductive patterns 14 that are to be connected to a substrate (these may be points that differ from the center points of the pads P in the direction of the XY horizontal plane), it is possible in the present invention to form the connecting points in a shape of a rectangular or circular land and connect a gold ball formed at one end of a gold wire to these lands by a wire bonding method, with the other end of this gold wire being connected to a connecting terminal such as the lead of a lead frame, etc. In this structure as well, the gold wires can be avoided from crossing to each other or from excessively getting close to each other, thus assuring a desirable arrangement.

In the present invention, the conductive patterns can be formed using other materials and forming methods from those described above. For example, the conductive patterns can be formed by a method that uses laser light to irradiate and cure a photo-setting resin that contains a conductive powder or can be formed using a conductive polymer. Alternatively, the conductive patterns can be formed by electroplating or electroless plating or by a combination of these methods with etching, or the conductive patterns can be formed by metal vapor deposition using CVD (chemical vapor deposition) or PVD (physical vapor deposition, including vacuum evaporation, sputtering and ion plating, etc.). When the conductive patterns are formed by a photo-setting resin that contains a conductive powder, the electrical resistance of the conductive patterns can be lowered (from the shortening of the inter-particle distance of the conductive powder during condensation or shrinkage) by condensing the thermosetting resin by laser irradiation or by using a thermosetting resin that shrinks when cured.

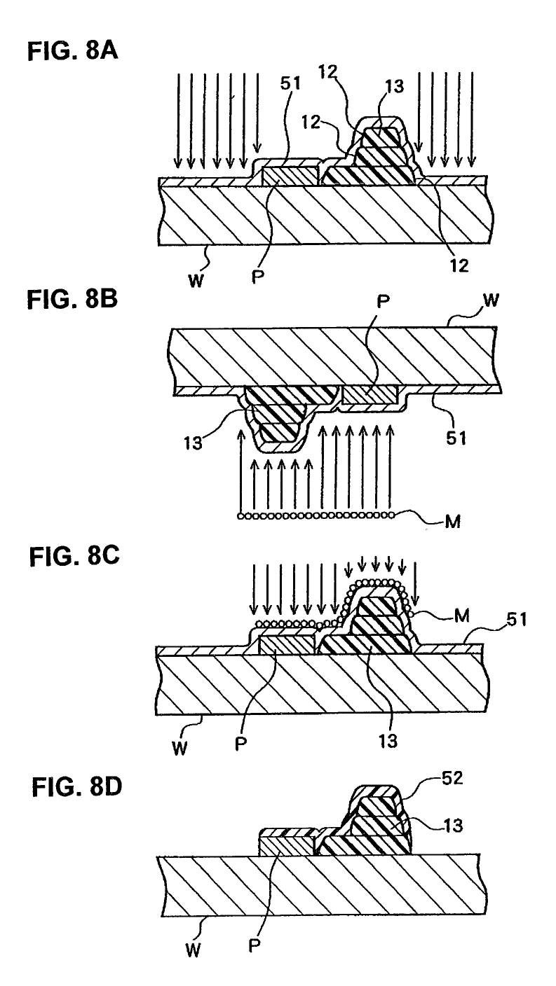

Furthermore, the conductive patterns can be formed using an electrostatic duplicating process. For instance, after creating a state in which the pads P and trapezoidal portions 13 remain on the wafer W (by the processes of FIGS. 2A through 2C), a photosensitive body 51 consisting of a dielectric material is first applied as a coating as shown in FIG. 8A. As an exposure step, a voltage is applied to this photosensitive body 51 so that the photosensitive body is charged to, for example, a positive polarity. In this state, the portions other than the locations where the wiring pattern is to be formed are irradiated with a laser. In the irradiated portions, the photosensitive body 51 is endowed with conductivity, and the charge is reduced, thus removing the charge.

Next, as shown in FIG. 8B, the wafer W is turned upside down. Then, as a development process, the wafer W is caused to approach a metal powder body M that is charged to the polarity opposite from that of the photosensitive body 51 on the surface of the wafer W, so that the metal powder body M is adsorbed on the photosensitive body 51.

Next, as shown in FIG. 8C, the adsorbed metal powder body M is heated by laser irradiation as a fixing step, so that the metal powder body M is melted, shrunk and sintered on the previously formed photosensitive body 51, thus forming conductive patterns 52 (FIG. 8D) formed by the modification of the photosensitive body 51, and the unnecessary portions that have not been irradiated are removed by solvents. The subsequent steps are the same as in the above-described embodiment shown in FIG. 2E.

When the electrostatic duplicating process is used, fine conductive patterns can be formed with good efficiency. Instead of a method that uses a photosensitive body 51 and a metal powder body M, it is also possible to add carbon black to a photo-setting resin and cure this resin by means of laser irradiation. Moreover, it is also possible to lower the electrical resistance by adding carbon black up to the percolation region.

In the above-described embodiment and respective modifications, it is further possible to set the laser intensity at a level that allows removal (ablation) of the alumina formed on the surfaces of the pads P during irradiation of the insulator or conductive substance by means of the laser. Alternatively, it is also possible to perform a similar removal of alumina by heating only the underlayer pads P to a high temperature by laser irradiation from two directions or to perform a similar removal of alumina by irradiating the exposed pads P with the laser prior to the irradiation of the insulator or conductive substance.

1. A semiconductor device manufacturing method comprising:
a conductive pattern formation step that forms a plurality of conductive patterns, which are electrically connected at one ends thereof to a plurality of pads, on an integrated circuit on which said plurality of pads are formed, and
a connecting step that connects connecting points located at other ends of said conductive patterns to a substrate; wherein
a disposition of said connecting points that differs from a disposition of said pads is obtained by means of said conductive patterns.

2. The semiconductor device manufacturing method according to claim 1, wherein said conductive pattern formation step includes a protective layer formation step that forms a resin layer as an outer layer on said conductive patterns to protect said conductive patterns.

3. The semiconductor device manufacturing method according to claim 1, wherein in said conductive pattern formation step intersection portions in which said plurality of conductive patterns intersect are formed.

4. The semiconductor device manufacturing method according to claim 1, wherein said conductive pattern formation step includes a bump formation step in which bumps used for flip-chip bonding are formed on said connecting points.

5. The semiconductor device manufacturing method according to claim 4, wherein said bump formation step includes:
a trapezoidal portion formation step that forms a resin layer on a surface of said integrated circuit; and
a conductive layer formation step that forms a conductive layer as an outer layer on said resin layer.

6. The semiconductor device manufacturing method according to claim 5, wherein said resin layer possesses elasticity when being cured.

7. The semiconductor device manufacturing method according to any one of claims 1 through 5, wherein said conductive patterns are formed by sintering a conductive powder.

8. The semiconductor device manufacturing method according to any one of claims 1 through 5, wherein said conductive patterns are comprised of a photo-setting resin that contains a conductive powder.

9. The semiconductor device manufacturing method according to claim 2, 5 or 6, wherein said resin layer is comprised of an insulating photo-setting resin.

10. The semiconductor device manufacturing method according to any one of claims 1 through 6 wherein said conductive pattern formation step is performed simultaneously for a plurality of integrated circuits that are formed on a wafer prior to dicing.

11. The semiconductor device manufacturing method according to claim 7, wherein said conductive pattern formation step is performed simultaneously for a plurality of integrated circuits that are formed on a wafer prior to dicing.

12. The semiconductor device manufacturing method according claim 8, wherein said conductive pattern formation step is performed simultaneously for a plurality of integrated circuits that are formed on a wafer prior to dicing.

13. The semiconductor device manufacturing method according to claim 9, wherein said conductive pattern formation step is performed simultaneously for a plurality of integrated circuits that are formed on a wafer prior to dicing.

14. The semiconductor device manufacturing method according to claim 2, wherein said protective layer formation step is performed simultaneously for a plurality of integrated circuits that are formed on a wafer prior to dicing.
